(19) United States
(12) Patent Application Publication
(10) Pub. No.: US 2024/0229287 A1
(43) Pub. Date: Jul. 11, 2024

(54) ANODIZED FILM STRUCTURE

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 18/558,360

(22) PCT Filed: May 3, 2022
(86) PCT No.: PCT/KR2022/006342

§ 371 Date: Oct. 31, 2023

(30) Foreign Application Priority Data
May 6, 2021 (KR) 10-2021-0058695

(51) Int. Cl. C25D 11/18

(52) U.S. Cl. CPC C25D 11/18

(57) ABSTRACT

An anodized film structure according to the present invention comprises: a body, formed from an anodized film material, which is formed by anodizing a base metal and then removing the base metal; through holes having a greater inner width than pores formed during anodizing, and formed through the body; and an inner metal layer provided inside the body. Provided is the anodized film structure having enhanced physical and/or electrical properties to solve the problem of brittle fractures and impart partial conductivity.

### TECHNICAL FIELD

The present disclosure relates to an anodic aluminum oxide film structure.

### BACKGROUND ART

An anodic aluminum oxide film has a small amount of thermal deformation under a high temperature atmosphere and has electrical insulation properties. Studies are being conducted to utilize these physical and/or electrical characteristics in various fields.

However, since the anodic aluminum oxide film is manufactured in the form of a thin plate by anodizing a metal base material, there is a high possibility that brittle fracture occurs in the anodic aluminum oxide film after the metal base material is removed. Therefore, in order to use the anodic aluminum oxide film as a structure, the problem of brittle fracture has to be solved.

Meanwhile, the anodic aluminum oxide film has electrical insulation properties. For this reason, in an anodic aluminum oxide film structure using the anodic aluminum oxide film, it is necessary to consider how to implement a configuration to provide at least partial conductivity in addition to the insulation properties.

As such, for the use of the anodic aluminum oxide film as a structure, there is a need to improve the physical and/or electrical properties of the anodic aluminum oxide film.

### DOCUMENTS OF RELATED ART

### Patent Documents

(Patent Document 1) Korean Patent Application Publication No. 10-2017-0068241

### DISCLOSURE

### Technical Problem

Accordingly, the present disclosure has been made keeping in mind the above problems occurring in the related art, and an objective of the present disclosure is to provide an anodic aluminum oxide film structure that improves the physical and/or electrical properties of an anodic aluminum oxide film.

### Technical Solution

In order to accomplish the above objective, according to one aspect of the present disclosure, there is provided an anodic aluminum oxide film structure, including: a body made of an anodic aluminum oxide film that is formed by anodizing a base metal and then removing the base metal; a plurality of through-holes formed through the body and having a larger inner width than pores formed during anodization; and a plurality of inner metal layers provided inside the body.

In addition, the anodic aluminum oxide film structure may further include: a surface metal layer formed on a surface of the body. Here, the surface metal layer may be connected to each of the inner metal layers.

In addition, each of the inner metal layers may be formed on an inner wall of each of the through-holes and may be exposed toward the through-hole.

In addition, each of the inner metal layers may be formed around each of the through-holes and may not be exposed toward the through-hole.

In addition, each of the inner metal layers may be formed to surround at least a portion of each of the through-holes, and the anodic aluminum oxide film may exist between each of the inner metal layers and each of the through-holes.

In addition, the anodic aluminum oxide film structure may further include: an upper surface metal layer formed on an upper surface of the body; and a lower surface metal layer formed on a lower surface of the body.

In addition, each of the inner metal layers may be formed by stacking a plurality of metal layers in a thickness direction of the body.

In addition, the body may include a plurality of bodies stacked on each other.

In addition, the body may include a plurality of bodies stacked on each other, and inner metal layers formed in the respective bodies may be provided at the same position with respect to respective vertical lines.

In addition, the body may include a plurality of bodies stacked on each other, and inner metal layers formed in the respective bodies may be provided at different positions with respect to respective vertical lines.

In addition, the anodic aluminum oxide film structure may further include: a surface metal layer formed on a surface of the body and connecting the plurality of inner metal layers to each other. Here, the surface metal layer may be grounded.

Meanwhile, according to another aspect of the present disclosure, there is provided an anodic aluminum oxide film structure, including: a body made of an anodic aluminum oxide film that is formed by anodizing a base metal and then removing the base metal; a plurality of through-holes formed through the body and having a larger inner width than pores formed during anodization; a plurality of inner metal layers each of which is provided on an inner wall of each of the through-holes to prevent the anodic aluminum oxide film from being exposed toward the through-hole; and a surface metal layer formed on a surface of the body to connect the plurality of inner metal layers to each other.

In addition, the anodic aluminum oxide film structure may further include: a plurality of fine trenches having a depth and a width and formed on a surface of each of the inner metal layer. Here, the fine trenches may be formed to extend in a thickness direction of the body, and the fine trenches may be repeatedly formed in a circumferential direction of each of the through-holes.

In addition, the depth and the width of the fine trenches may range from 20 nm to 1 μm.

Meanwhile, according to another aspect of the present disclosure, there is provided an anodic aluminum oxide film structure, including: a body made of an anodic aluminum oxide film that is formed by anodizing a base metal and then removing the base metal; and an inner metal layer provided inside the body. Here, the inner metal layer may be provided with a plurality of fine trenches that are formed at a bonding interface between the inner metal layer and the body and are in close contact with inner walls of pores of the body.

### Advantageous Effects

The present disclosure provides an anodic aluminum oxide film structure that improves the physical and/or electrical properties of an anodic aluminum oxide film.

### DESCRIPTION OF DRAWINGS

FIG. 1(a) is a plan view illustrating an anodic aluminum oxide film structure according to a first embodiment of the present disclosure.

FIG. 1(b) is a sectional view taken along line A-A′ of FIG. 1(a).

FIG. 2(a) is a plan view illustrating electrically conductive contact pins inserted into through-holes of the anodic aluminum oxide film structure according to the first embodiment of the present disclosure.

FIG. 2(b) is a sectional view taken along line A-A′ of FIG. 2(a).

FIGS. 3(a) to 7(c) are views illustrating a method of manufacturing the anodic aluminum oxide film structure according to the first embodiment of the present disclosure.

FIG. 8 is a view illustrating an inner wall of each through-hole of the anodic aluminum oxide film structure according to the first embodiment of the present disclosure.

FIG. 9 is a plan view illustrating an anodic aluminum oxide film structure according to a second embodiment of the present disclosure.

FIG. 10 is a sectional perspective view illustrating the anodic aluminum oxide film structure according to the second embodiment of the present disclosure.

FIGS. 11(a) to 14(b) are views illustrating a method of manufacturing the anodic aluminum oxide film structure according to the second embodiment of the present disclosure.

FIG. 15(a) is a plan view illustrating an anodic aluminum oxide film structure according to a third embodiment of the present disclosure.

FIG. 15(b) is a sectional view taken along line A-A′ of FIG. 15(a).

FIG. 16(a) is a plan view illustrating an anodic aluminum oxide film structure according to a fourth embodiment of the present disclosure.

FIG. 16(b) is a sectional view taken along line A-A′ of FIG. 16(a).

FIG. 17(a) is a plan view illustrating an anodic aluminum oxide film structure according to a fifth embodiment of the present disclosure.

FIG. 17(b) is a sectional view taken along line A-A′ of FIG. 17(a).

FIG. 18 is a plan view illustrating an anodic aluminum oxide film structure according to a sixth embodiment of the present disclosure.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses of films and regions in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise”, “include”, “have”, etc. when used herein, specify the presence of stated features, integers, steps, operations, elements, components, and/or combinations thereof but do not preclude the presence or addition of one or more other features, integers, steps, operations, elements, components, and/or combinations thereof.

Hereinafter, exemplary embodiments of the present disclosure will be described in detail with reference to the accompanying drawings. In describing various embodiments, the same reference numerals will be used throughout different embodiments and the description to refer to the same or like elements or parts. In addition, the configuration and operation already described in other embodiments will be omitted for convenience.

In the following description, first to sixth embodiments will be described separately, but embodiments that combine the components of each embodiment are also included in the exemplary embodiments of the present disclosure.

### First Embodiment

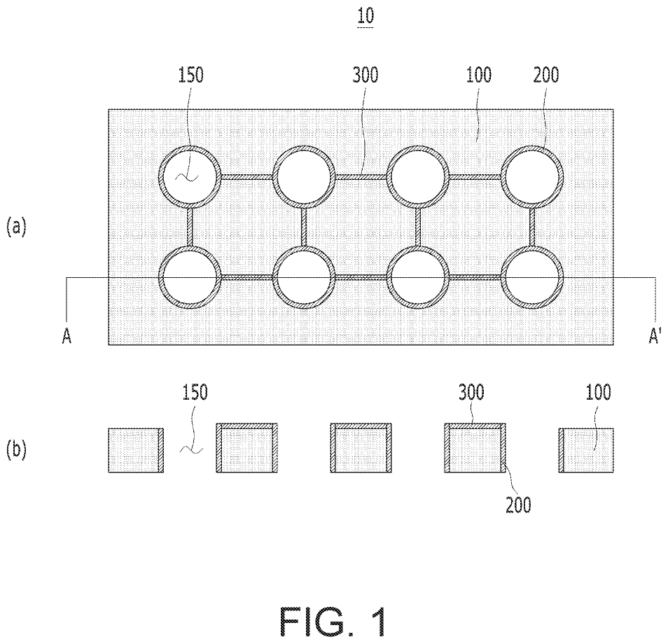

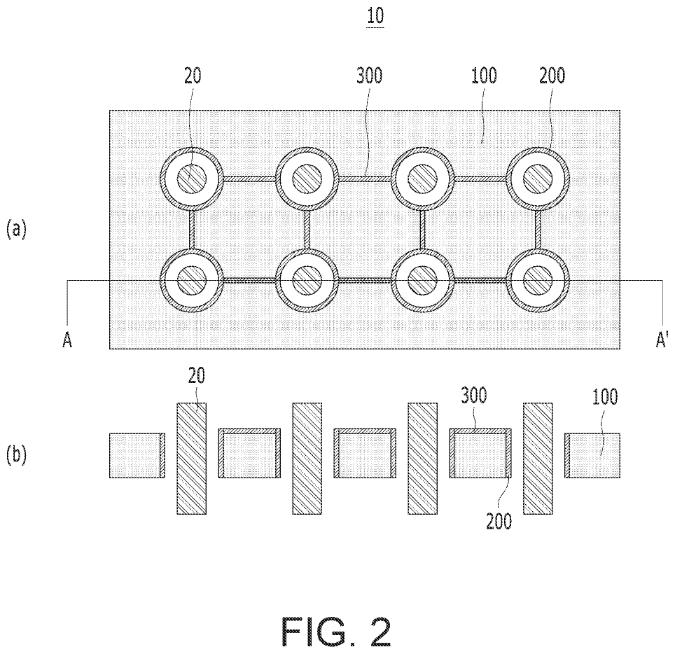

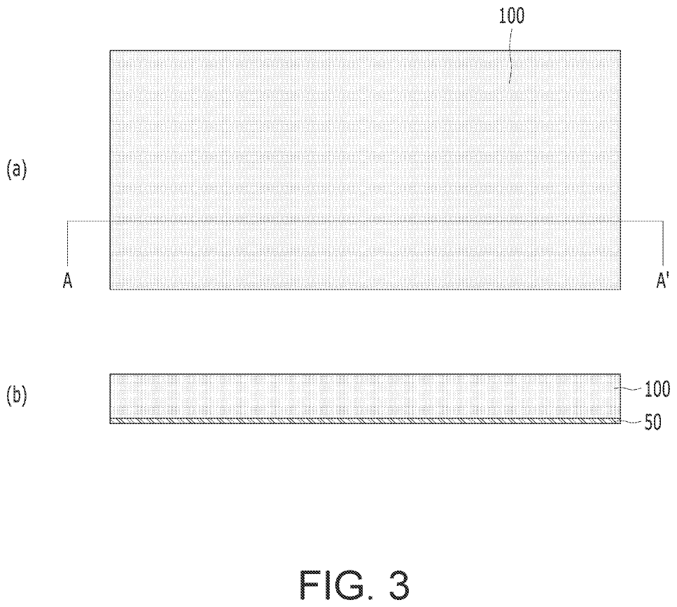

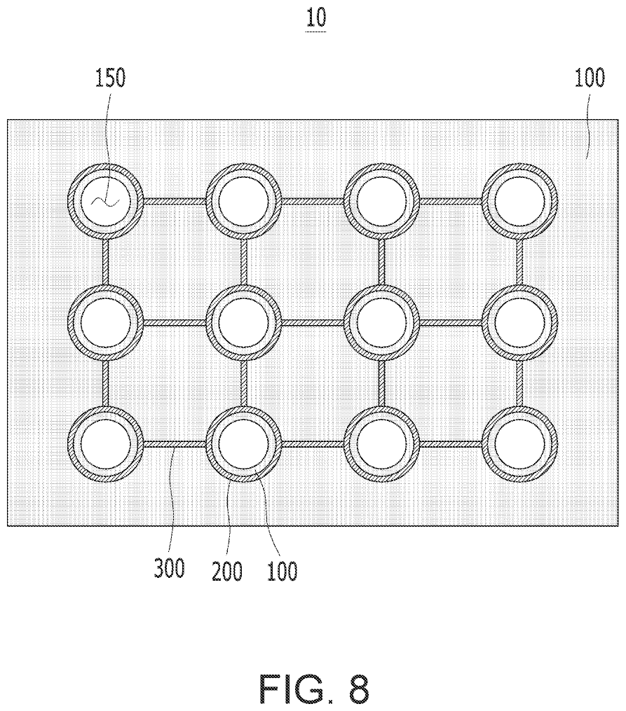

Hereinafter, an anodic aluminum oxide film structure according to the first embodiment of the present disclosure will be described with reference to FIGS. 1 to 8. FIG. 1(a) is a plan view illustrating the anodic aluminum oxide film structure 10 according to the first embodiment of the present disclosure. FIG. 1(b) is a sectional view taken along line A-A′ of FIG. 1(a). FIG. 2(a) is a plan view illustrating electrically conductive contact pins 20 inserted into through-holes of the anodic aluminum oxide film structure 10 according to the first embodiment of the present disclosure. FIG. 2(b) is a sectional view taken along line A-A′ of FIG. 2(a). FIGS. 3(a) to 7(c) are views illustrating a method of manufacturing the anodic aluminum oxide film structure 10 according to the first embodiment of the present disclosure. FIG. 8 is a view illustrating an inner wall of each through-hole 150 of the anodic aluminum oxide film structure 10 according to the first embodiment of the present disclosure.

Referring to FIG. 1, the anodic aluminum oxide film structure 10 according to the first embodiment of the present disclosure includes: a body 100 made of an anodic aluminum oxide film that is formed by anodizing a base metal and then removing the base metal; a plurality of through-holes 150 formed through the body and having a larger inner width than pores 121 formed during anodization; and a plurality of inner metal layers 200 provided inside the body 110.

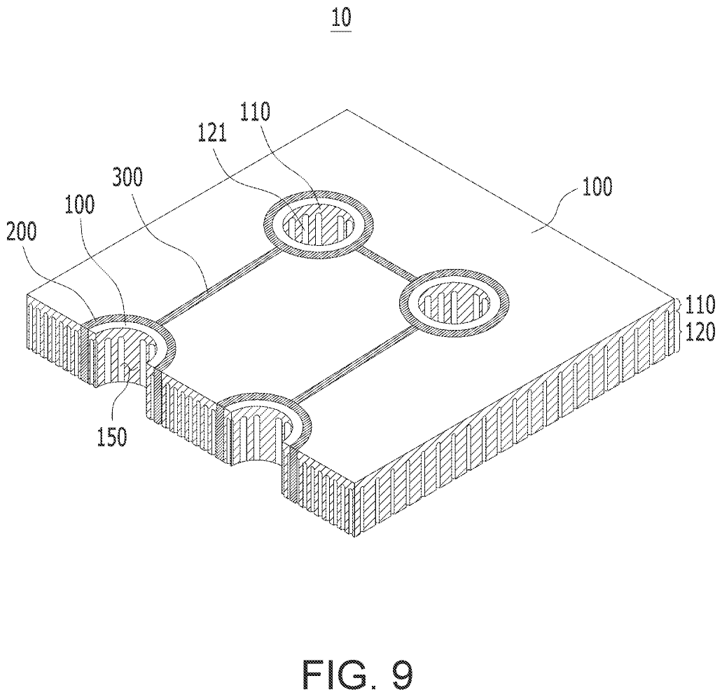

The body 100 is made of the anodic aluminum oxide film. The anodic aluminum oxide film means a film formed by anodizing a metal as a base material, and the pores 121 mean holes formed in the process of forming the anodic aluminum oxide film by anodizing the metal. For example, when the metal as the base material is aluminum (Al) or an aluminum alloy, the anodization of the base material forms the anodic aluminum oxide film consisting of anodized aluminum (Al₂O₃) on a surface of the base material. However, the metal is not limited thereto, and includes Ta, Nb, Ti, Zr, Hf, Zn, W, Sb, or an alloy of these metals. The resulting anodic aluminum oxide film includes a barrier layer 110 in which no pores 121 are formed therein vertically, and a porous layer 120 in which pores 121 are formed therein. After removing the base material on which the anodic aluminum oxide film having the barrier layer 1110 and the porous layer 120 is formed, only the anodic aluminum oxide film consisting of anodized aluminum (Al₂O₃) remains. The anodic aluminum oxide film may have a structure in which the barrier layer 110 formed during the anodization is removed to expose the top and bottom of the pores 121, or a structure in which the barrier layer 110 formed during the anodization remains to close one of the top and bottom of the pores 121 (see FIG. 9).

The anodic aluminum oxide film has a coefficient of thermal expansion of 2 to 3 ppm/° C. With this range, the anodic aluminum oxide film only undergoes a small amount of thermal deformation due to temperature when exposed to a high temperature environment. Therefore, the anodic aluminum oxide film structure 10 can be used without thermal deformation even in a high temperature environment.

The anodic aluminum oxide film structure 10 includes the through-holes 150 formed through the body 100 and having a larger inner width than the pores 121 formed during the anodization. The through-holes 150 are formed through upper and lower surfaces of the body 100, and may be formed by etching as will be described later.

The anodic aluminum oxide film structure 10 includes the inner metal layers 200 provided inside the body 100. The inner metal layers 200 are provided inside the body 100. That is, the inner metal layers are provided between the upper and lower surfaces of body 100. An upper surface of each of the inner metal layers 200 may be exposed toward the upper surface of the body 100 and a lower surface of each of the inner metal layers 200 may be exposed toward the lower surface of the body 100.

Each of the inner metal layers 200 may be formed on an inner wall of each of the through-holes 150 and exposed toward the through-hole 150, or may be formed around each of the through-holes 150 and not exposed toward the through-hole 150.

The inner metal layers 200 include a metal selected from the group consisting of copper (Cu), silver (Ag), gold (Au), rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. However, the metal constituting the inner metal layers 200 is not limited thereto and includes any metal that can improve the physical and/or electrical properties of the anodic aluminum oxide film structure 10.

When the inner metal layers 200 formed on the inner walls of the through-holes 150 are made of a metal having high wear resistance or hardness, the wear resistance or hardness of the inner walls of the through-holes 150 can be improved. With this, it is possible to minimize generation of foreign substances inside the through-holes 150 that come off from the body 100 made of the anodic aluminum oxide film.

Meanwhile, when the inner metal layers 200 formed on the inner walls of the through-holes 150 are made of a metal having high electrical conductivity, the electrical conductivity of the inner walls of the through-holes 150 can be improved. With this, when a signal transmission member provided inside the through-holes 150 for the purpose of transmitting an electric signal comes into contact with the inner walls of the through-holes 150, signal transmission can be performed more stably.

The anodic aluminum oxide film structure 10 includes a surface metal layer 300 formed on a surface of the body 100. The surface metal layer 300 may be formed on the upper surface and/or lower surface of the body 100. The surface metal layer 300 includes a metal selected from the group consisting of copper (Cu), silver (Ag), gold (Au), rhodium (Rd), platinum (Pt), iridium (Ir), palladium, and an alloy of these metals; the group consisting of a palladium-cobalt (PdCo) alloy and a palladium-nickel (PdNi) alloy; or the consisting of a nickel-phosphor (NiPh) alloy, a group nickel-manganese (NiMn), a nickel-cobalt (NiCo), and a nickel-tungsten (NiW) alloy. However, the metal constituting the surface metal layer 300 is not limited thereto and includes any metal that can improve the physical and/or electrical properties of the anodic aluminum oxide film structure 10. In addition, the surface metal layer 300 may be made of a material the same as or different from that of the inner metal layers 200.

Each of the inner metal layers 200 is formed on the inner wall of each of the through-holes 150 or around each of the through-holes 150, and the surface metal layer 300 is connected to each of the inner metal layers 200. At least one end of the surface metal layer 300 may be connected to each of the inner metal layers 200, or each end of the surface metal layer 300 may be connected to each of the inner metal layers 200.

The plurality of inner metal layers 200 may be connected to each other by a plurality of surface metal layers 300. The inner metal layers 200 formed on the inner walls of the through-holes 150 are connected and integrated by the surface metal layers 300, so that peeling of the inner metal layers 200 formed on the inner walls of the through-holes 150 can be minimized. In addition, the surface metal layers 300 and the inner metal layers 200 may be connected to each other so that the inner metal layers 200 are grounded.

Referring to FIG. 2, the anodic aluminum oxide film structure 10 according to the first embodiment of the present disclosure may be a plate in which an electrically conductive contact pin 20 is installed. The electrically conductive contact pin 20 is provided in an inspection apparatus and is used to transmit electrical signals by making electrical and physical contact with an inspection object. The inspection apparatus may be an inspection apparatus used in a semiconductor manufacturing process, for example, a probe card or a test socket. However, the inspection apparatus is not limited thereto and includes any apparatus for checking whether the inspection object is defective by applying electricity.

The electrically conductive contact pin 20 is provided in each of the through-holes 150 of the anodic aluminum oxide film structure 10. The electrically conductive contact pin 20 may be provided in the through-hole 150 so that it can make contact with the inner wall of the through-hole 150 while sliding vertically in the through-hole 150, or may be provided in the through-hole 150 to be fixedly installed in the through-hole 150.

The electrically conductive contact pin 20 illustrated in FIG. 2 may be a contact pin for transmitting a ground signal, a contact pin for transmitting a power signal, or a contact pin for transmitting an operation signal. Contact pins that transmit the same signal may be electrically connected to each other as a group through the inner metal layers 200 and the surface metal layers 300. For example, in the case of the contact pin for transmitting a ground signal, a plurality of contact pins for transmitting a ground signal may be connected to each other as a group and commonly grounded. With this, these contact pins perform the function of removing noise from operation signals transmitted by contact pins for transmitting an operation signal. In the case of the contact pin for transmitting a power signal, a plurality of contact pins for transmitting a power signal may be connected to each other as a group to transmit the same power signal. In addition, in the case of the contact pin for transmitting an operation signal, a plurality of contact pins for transmitting an operation signal may be connected to each other as a group to transmit the same operation signal.

Hereinafter, a method of manufacturing the anodic aluminum oxide film structure 10 according to the first embodiment of the present disclosure will be described with reference to FIGS. 3 to 9.

First, referring to FIG. 3, FIG. 3(a) is a plan view illustrating a body 100, and FIG. 3(b) is a sectional view taken along line A-A′ of FIG. 3(a).

The body 100 made of an anodic aluminum oxide film is prepared. The anodic aluminum oxide film is formed by anodizing a base metal. After anodizing the base metal, the base metal is removed to prepare the body 100 composed only of the anodic aluminum oxide film.

A seed layer 50 is provided on a lower surface of the body 100. The seed layer 50 may be provided on the lower surface of the body 100 before an inner space 40 is formed in the body 100. Meanwhile, a support substrate (not illustrated) is formed under the body 100 to improve handling of the body 100. In this case, the seed layer 50 may be formed on an upper surface of the support substrate, and then the body 100 having the inner space 40 may be coupled to the support substrate. The seed layer 50 may be made of copper (Cu), and may be formed by a deposition method.

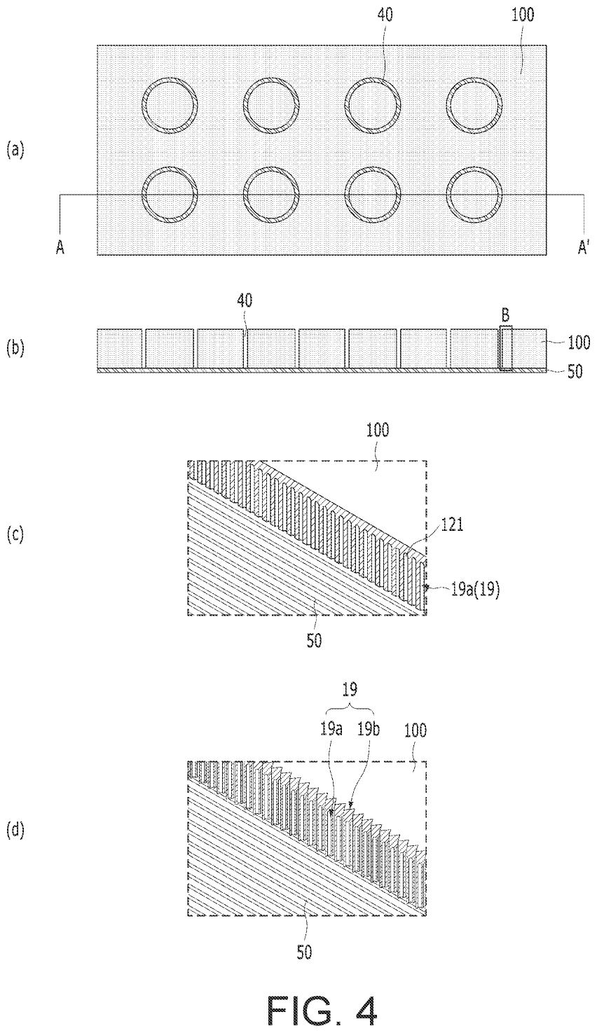

Next, referring to FIG. 4, FIG. 4(a) is a plan view illustrating the body 100 in which a plurality of inner spaces 40 are formed, FIG. 4(b) is a sectional view taken along line A-A′ of FIG. 4(a), and FIGS. 4(c) and 4(d) are enlarged views illustrating side walls at portion “B” in FIG. 4(b).

The inner spaces 40 are formed in the body 100. The inner spaces 40 may be formed by wet-etching portions of the body 100 made of the anodic aluminum oxide film. To this end, a photoresist is provided on the upper surface of the body 100 and patterned, and then the anodic aluminum oxide film in patterned and open areas reacts with an etchant to form the inner spaces 40.

An uneven portion 19 is formed on each sidewall of each of the inner spaces 40 of the body 100. The uneven portion 19 is formed along each sidewall of each of the inner spaces 40 and extends long in the vertical length direction of the body 100. A plurality of uneven portions 19 are formed to extend long in the vertical direction of the body 100. The uneven portions are configured as a plurality of grooves spaced apart from each other along each sidewall of each of the inner spaces. The uneven portions 19 include a plurality of pore-type uneven portions 19a formed when pores 121 formed during manufacture of the anodic aluminum oxide film are opened during an etching process, and a plurality of etching-type uneven portions 19b formed in response to an uneven interface of the photoresist during etching of the anodic aluminum oxide film 10.

Since the pore-type uneven portions 19a are formed by the pores 121 formed during manufacture of the body 100 made of the anodic aluminum oxide film, grooves forming the pore-type uneven portions 19a have a width and a depth in the range of 10 nm to 1 μm.

The etching-type uneven portions 19b may be formed separately from the pores 121 according to the shape of the photoresist when the inner spaces 40 are formed by etching the body 100 made of the anodic aluminum oxide film. The body 100 made of the anodic aluminum oxide film reacts with the etchant in the open areas of the photoresist and are etched vertically along the shape of the open patterns of the photoresist to form the inner spaces 40. When the photoresist is patterned so that a pattern interface of each open area of the photoresist has an uneven shape, each sidewall of each of the inner spaces 40 of the body 100 also has uneven patterns in a horizontal cross section. These uneven patterns on each sidewall of each of the inner spaces 40 become the etching-type uneven portions 19b. The pore-type uneven portions 19a are formed on walls of the etching-type uneven portions 19b. Since the pore-type uneven portions 19a are formed along the walls of the etching-type uneven portions 19b, from a macroscopic perspective, the uneven portions 19 include the pore-type uneven portions 19a and the etching-type uneven portions 19b. The width and depth of grooves forming the etching-type uneven portions 19b are configured to be larger than those of grooves forming the pore-type uneven portions 19a. Preferably, the width and depth of the grooves forming the etching-type uneven portions 19b range from 100 nm to 30 μm. As such, since the uneven portions 19 according to the embodiment of the present disclosure include the pore-type uneven portions 19a and the etching-type uneven portions 19b, the surface area of each sidewall of each of inner spaces 40. With this, the surface area at a bonding interface of an inner metal layer 200 formed in each of the inner spaces 40 can be increased, thereby increasing a bonding force of the inner metal layer 200 to the body 100 made of the anodic aluminum oxide film.

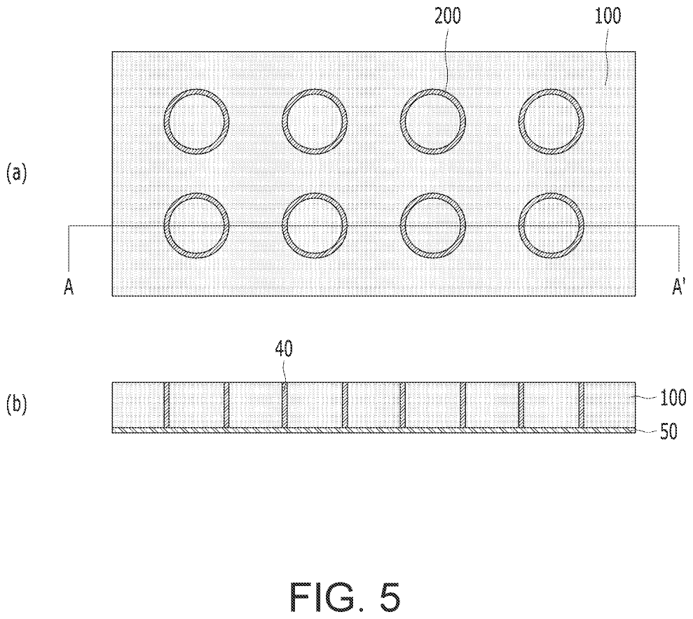

Next, referring to FIG. 5, FIG. 5(a) is a plan view illustrating the body 100 in which a plurality of inner metal layers 200 are formed in the inner spaces 40, and FIG. 5(b) is a sectional view taken along line A-A′ of FIG. 5(a).

The inner metal layers 200 are formed in the inner spaces 40 by electroplating using the seed layer 50. The inner metal layers 200 include at least one metal selected from the group consisting of copper (Cu), silver (Ag), gold (Au), rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. However, the metal constituting the inner metal layers 200 is not limited thereto and includes any metal that can improve the physical and/or electrical properties of the anodic aluminum oxide film structure 10.

After the plating process is completed, a planarization process is performed. The metal protruding from the upper surface of the body 100 is removed and planarized through a chemical mechanical polishing (CMP) process.

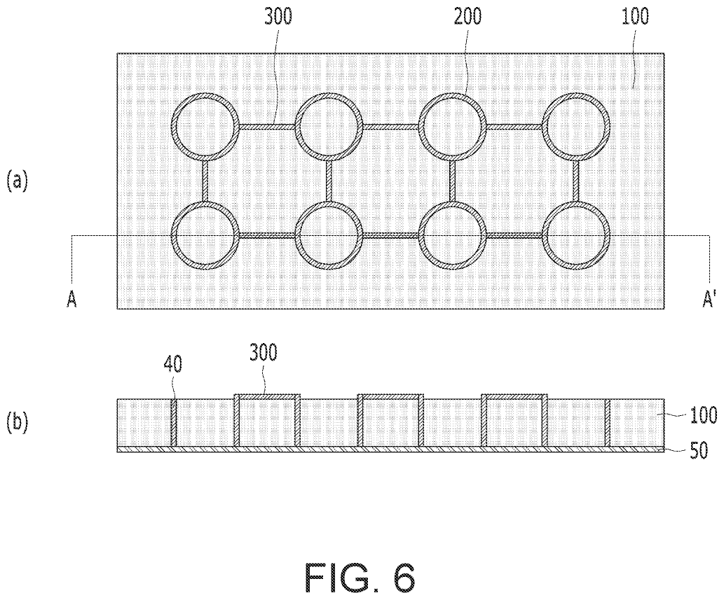

Next, referring to FIG. 6, FIG. 6(a) is a plan view illustrating the body 100 in which a plurality of surface metal layers 300 are formed on a surface of the body 100, and FIG. 6(b) is a sectional view taken along line A-A′ of FIG. 6(a).

A photoresist is formed on the surface of the body 100 and patterned, and then the surface metal layers 300 are formed in patterned and open areas. The surface metal layers 300 may be formed by electroplating using the previously formed inner metal layers 200. With this, the inner metal layers 200 and the surface metal layers 300 may be formed integrally.

The surface metal layers 300 include a metal selected from the group consisting of copper (Cu), silver (Ag), gold (Au), rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. However, the metal constituting the surface metal layers 300 is not limited thereto and includes any metal that can improve the physical and/or electrical properties of the anodic aluminum oxide film structure 10. In addition, the surface metal layers 300 may be made of a material the same as or different from that of the inner metal layers 200.

After the plating process is completed, a planarization process is performed. After the chemical mechanical polishing (CMP) process is completed, the photoresist is removed.

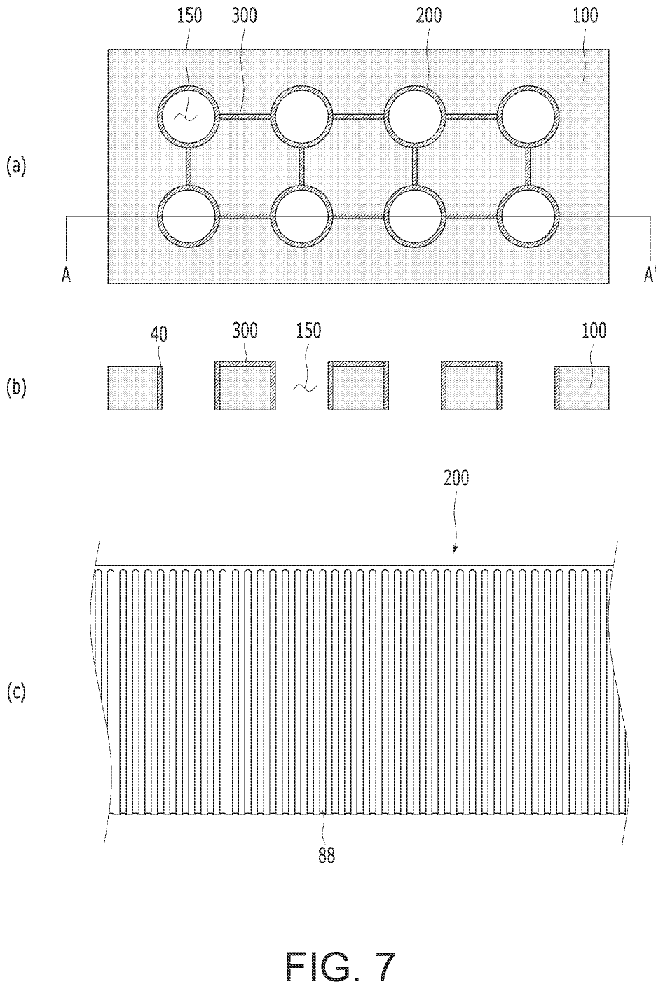

Next, referring to FIG. 7, FIG. 7(a) is a plan view illustrating the body 100 in which a plurality of through-holes 150 vertically passing through the body 100 are formed, FIG. 7(b) is a sectional view taken along line A-A′ of FIG. 7(a), and FIG. 7(c) is a view illustrating an inner wall of each of the through-holes 150.

A photoresist is provided on the surface of the body 100 and patterned, and then the anodic aluminum oxide film in patterned and open areas reacts with an etchant to form the through-holes 150. Then, the seed layer 50 provided under the body 100 is removed.

The inner metal layers 200 are provided on inner walls of the through-holes 150. The physical and/or electrical properties of the through-holes 150 are improved depending on the material of the inner metal layers 200. When the inner metal layers 200 are made of a material having high wear resistance or hardness, the physical properties of the through-holes 150 are improved. Alternatively, when the inner metal layers 200 are formed of a material having high electrical conductivity, the electrical properties of the through-hole 150 are improved.

Referring to FIG. 7(c), a plurality of fine trenches 88 having a depth and width are provided on a surface of each of the inner metal layers 200. The fine trenches 88 are formed on the inner wall of each of the through-holes 150 to extend in the thickness direction of the body 100 and are repeatedly formed in the circumferential direction of the through-hole 150.

The fine trenches 88 have a depth in the range of 20 nm to 1 μm and a width in the range of 20 nm to 1 μm. Here, because the fine trenches 88 are resulted from formation of pores formed during manufacture of a mold made of an anodic aluminum oxide film, the width and the depth of the fine trenches 88 are equal to or less than the diameter of the pores 121 of the body 100. Meanwhile, in the process of forming the inner spaces 40 in the body 100, portions of the pores 121 of the body 100 may be crushed by an etchant to at least partially form a fine trench 88 having a depth greater than the diameter of the pores 121 formed during anodization.

Since the body made of the anodic aluminum oxide film includes a large number of pores, at least portions of the body 100 are etched to form the inner spaces 40, and a metal filling material is formed in each of the inner spaces 40, the fine trenches 88 are provided on the inner wall of each of the through-holes 150 as a result of contact with the pores 121 of the mold. By the fine trenches 88, the surface area on a side surface of the through-hole 150 can be increased.

In addition, the inner metal layer 200 is provided with a plurality of fine trenches 88 that are formed at a bonding interface between each of the inner metal layers 200 and the body 100 and are in close contact with inner walls of pores 121 of the body 100. With this, a bonding force between the inner metal layer 200 and the body 100 can be improved.

### Second Embodiment

Next, the second embodiment according to the present disclosure will be described. However, the embodiments described below will be mainly described in terms of characteristic elements in comparison with the first embodiment, and descriptions of the same or similar elements to the first embodiment will be omitted.

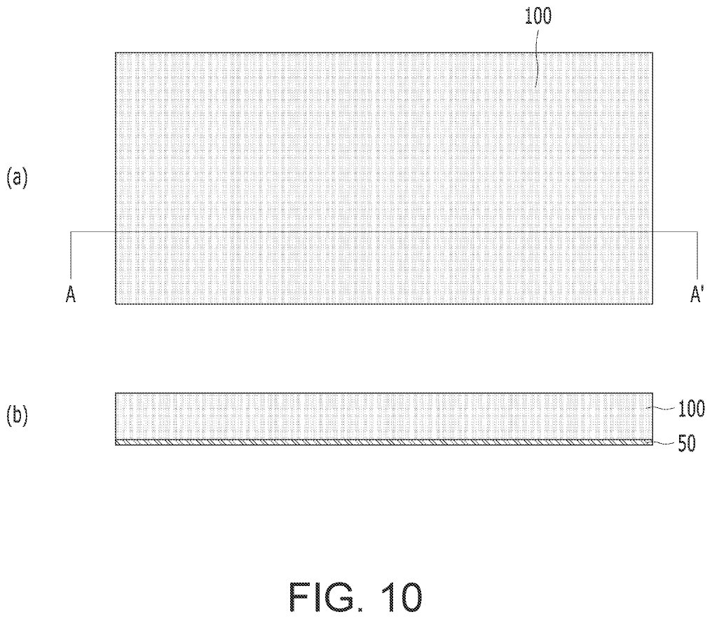

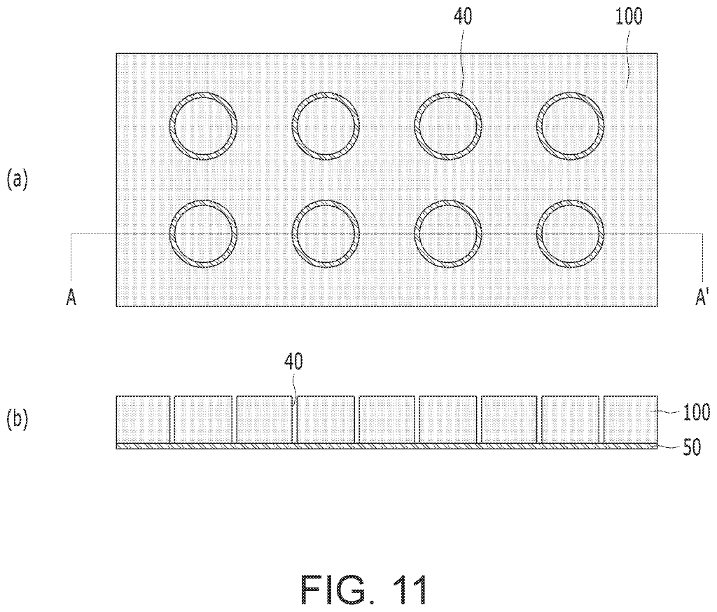

Hereinafter, an anodic aluminum oxide film structure 10 according to the second embodiment of the present disclosure will be described with reference to FIGS. 9(a) to 14(b). FIG. 9 is a plan view illustrating the anodic aluminum oxide film structure 10 according to the second embodiment of the present disclosure. FIG. 10 is a sectional perspective view illustrating the anodic aluminum oxide film structure 10 according to the second embodiment of the present disclosure. FIGS. 11(a) to 14 are views illustrating a method of manufacturing the anodic aluminum oxide film structure 10 according to the second embodiment of the present disclosure.

The anodic aluminum oxide film structure 10 according to the second embodiment of the present disclosure remains the same as the anodic aluminum oxide film structure 10 according to the first embodiment of the present disclosure, except for the configuration of a through-hole 150.

The anodic aluminum oxide film structure 10 according to the second embodiment includes a configuration in which an inner metal layer 200 is formed around a through-hole 150 so that the inner metal layer 200 is not exposed toward the through-hole 150. Each inner metal layer 200 is formed to surround at least a portion of each through-hole 150, and an anodic aluminum oxide film exists between each inner metal layer 200 and each through-hole 150.

Since a plurality of uneven portions 19 and a plurality of fine trenches 88 are provided at a bonding interface between each inner metal layer 200 and a body 100 made of an anodic aluminum oxide film, a plurality of inner metal layers 200 is bonded to the body 100 with a sufficient bonding force.

The anodic aluminum oxide film of the body 100 is exposedly provided on inner walls of a plurality of through-holes 150. The anodic aluminum oxide film provided on the inner walls of through-holes 150 is bonded to the inner metal layers 200 with a sufficient bonding force through the configuration of the uneven portions 19 and the fine trenches 88 at bonding interfaces with the inner metal layers 200.

Since the anodic aluminum oxide film of the body 100 is provided on the inner walls of the through-holes 150, the inner walls of the through-holes 150 have insulation properties.

An electrically conductive contact pin 20 is slidably provided in each of the through-holes 150. The anodic aluminum e film provided on the inner walls of the through-holes 150 includes a barrier layer 110 in which no pores 121 are formed therein and a porous layer 120 in which pores 121 are formed therein. By the porous layer 120, the bondability of the anodic aluminum oxide film provided on the inner walls of the through-holes 150 to the inner metal layers 200 can be improved, and at the same time, by the barrier layer 110 provided on the porous layer 120, the wear resistance of the inner walls of the through-holes 150 can be improved.

In addition, by the inner metal layers 200 formed around the through-holes 150 while surrounding the through-holes 150, signal interference between adjacent electrically conductive contact pins 20 can be blocked. In this case, each of the inner metal layers 200 may be connected to a surface metal layer 300 and grounded.

Hereinafter, a method of manufacturing the anodic aluminum oxide film structure 10 according to the second embodiment of the present disclosure will be described with reference to FIGS. 10(a) to 14(b).

First, referring to FIG. 10, FIG. 10(a) is a plan view illustrating a body 100, and FIG. 10(b) is a sectional view taken along line A-A′ of FIG. 10(a).

The body 100 made of an anodic aluminum oxide film is prepared. The anodic aluminum oxide film is formed by anodizing a base metal. After anodizing the base metal, the base metal is removed to prepare the body 100 composed only of the anodic aluminum oxide film. A seed layer 50 is provided on a lower surface of the body 100.

Next, referring to FIG. 11, FIG. 11(a) is a plan view illustrating the body 100 in which a plurality of inner spaces 40 are formed, and FIG. 11(b) is a sectional view taken along line A-A′ of FIG. 11(a).

The inner spaces 40 are formed in the body 100. The inner spaces 40 may be formed by wet-etching portions of the body 100 made of the anodic aluminum oxide film. To this end, a photoresist is provided on the upper surface of the body 100 and patterned, and then the anodic aluminum oxide film in patterned and open areas reacts with an etchant to form the inner spaces 40.

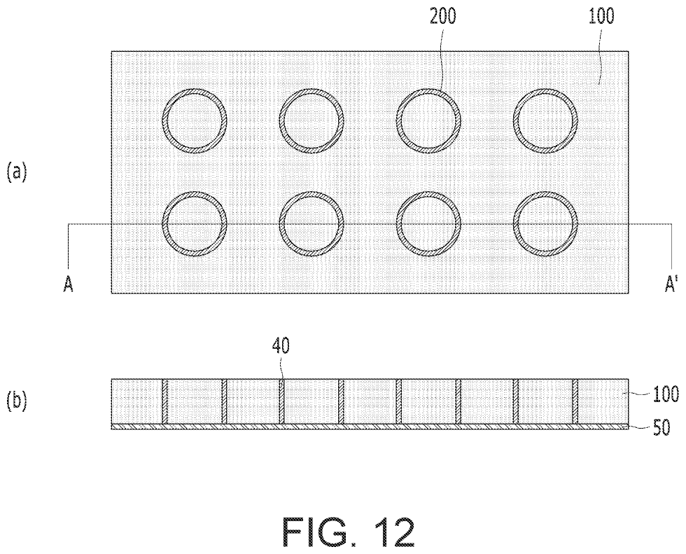

Next, referring to FIG. 12, FIG. 12(a) is a plan view illustrating the body 100 in which a plurality of inner metal layers 200 are formed in the inner spaces 40, and FIG. 12(b) is a sectional view taken along line A-A′ of FIG. 12(a).

The inner metal layers 200 are formed in the inner spaces 40 by electroplating using the seed layer 50. The inner metal layers 200 include at least one metal selected from the group consisting of copper (Cu), silver (Ag), gold (Au), rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. However, the metal constituting the inner metal layers 200 is not limited thereto and includes any metal that can improve the physical and/or electrical properties of the anodic aluminum oxide film structure 10.

After the plating process is completed, a planarization process is performed. The metal protruding from the upper surface of the body 100 is removed and planarized through a chemical mechanical polishing (CMP) process.

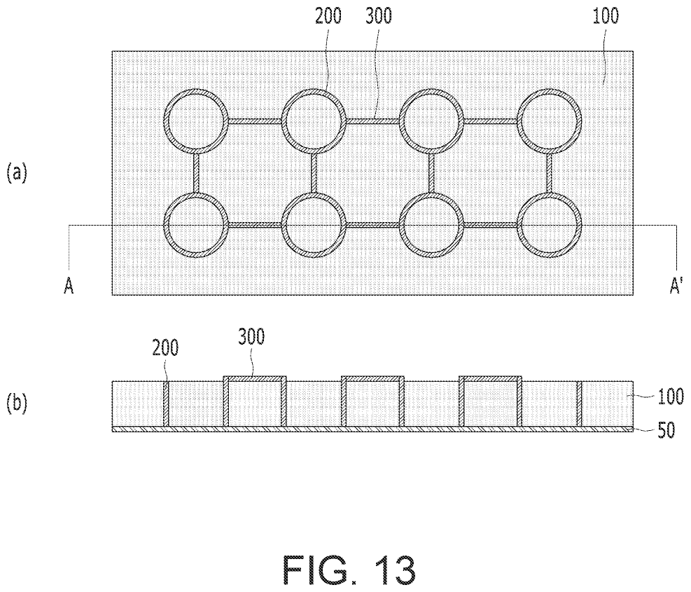

Next, referring to FIG. 13, FIG. 13(a) is a plan view illustrating the body 100 in which a plurality of surface metal layers 300 are formed on a surface of the body 100, and FIG. 13(b) is a sectional view taken along line A-A′ of FIG. 13(a).

A photoresist is formed on the surface of the body 100 and patterned, and then the surface metal layers 300 are formed in patterned and open areas. The surface metal layers 300 may be formed by electroplating using the previously formed inner metal layers 200. With this, the inner metal layers 200 and the surface metal layers 300 may be formed integrally.

The surface metal layers 300 include a metal selected from the group consisting of copper (Cu), silver (Ag), gold (Au), rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn), a nickel-cobalt (NiCo), and a nickel-tungsten (NiW) alloy. However, the metal constituting the surface metal layers 300 is not limited thereto and includes any metal that can improve the physical and/or electrical properties of the anodic aluminum oxide film structure 10. In addition, the surface metal layers 300 may be made of a material the same as or different from that of the inner metal layers 200.

After the plating process is completed, a planarization process is performed. After the chemical mechanical polishing (CMP) process is completed, the photoresist is removed.

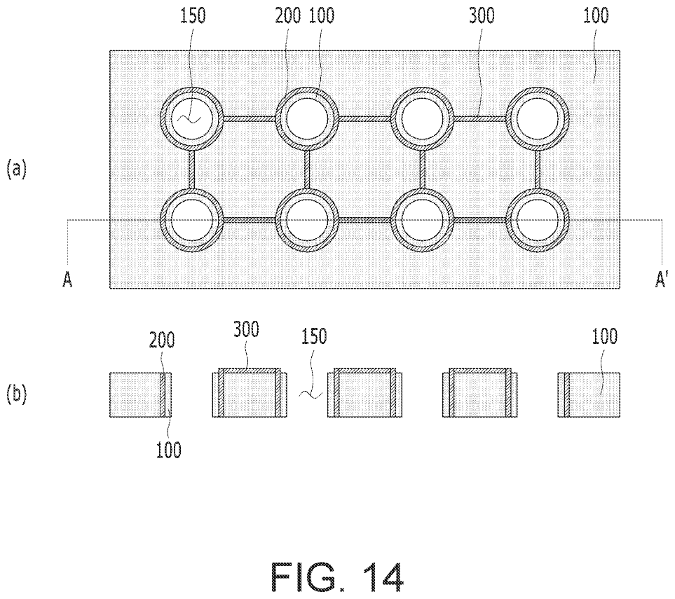

Next, referring to FIG. 14, FIG. 14(a) is a plan view illustrating the body 100 in which a plurality of through-holes 150 vertically passing through the body 100 are formed, and FIG. 14(b) is a sectional view taken along line A-A′ of FIG. 14(a).

A photoresist is provided on the surface of the body 100 and patterned, and then the anodic aluminum oxide film in patterned and open areas reacts with an etchant to form the through-holes 150. Then, the seed layer 50 provided under the body 100 is removed. The anodic aluminum oxide film of the body 100 is provided on inner walls of the through-holes 150.

### Third Embodiment

Next, the third embodiment according to the present disclosure will be described. However, the embodiments described below will be mainly described in terms of characteristic elements in comparison with the first embodiment, and descriptions of the same or similar elements to the first embodiment will be omitted.

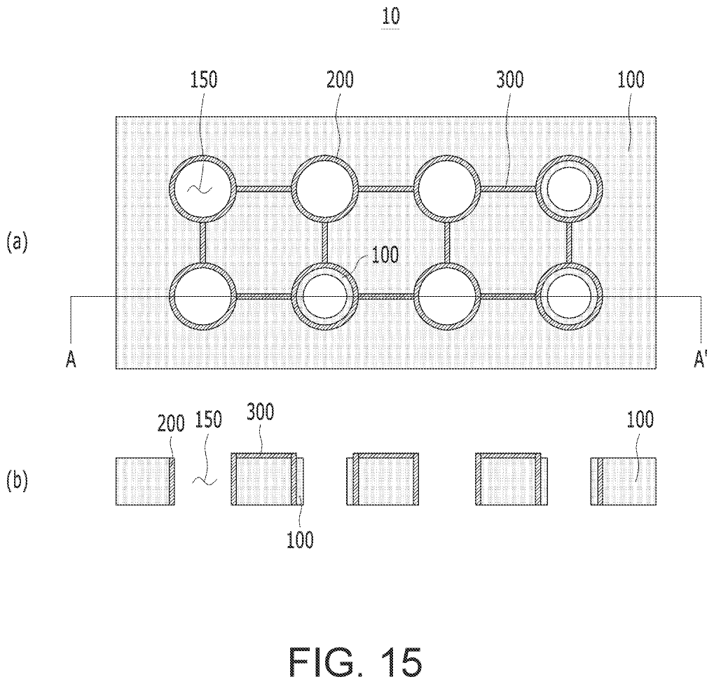

Hereinafter, an anodic aluminum oxide film structure 10 according to the third embodiment of the present disclosure will be described with reference to FIGS. 15(a) and 15(b). FIG. 15(a) is a plan view illustrating the anodic aluminum oxide film structure 10 according to the third embodiment of the present disclosure. FIG. 15(b) is a sectional view taken along line A-A′ of FIG. 15(a).

The anodic aluminum oxide film structure 10 according to the third embodiment of the present disclosure remains the same as the anodic aluminum oxide film structure 10 according to the first embodiment of the present disclosure, except for the configuration of a through-hole 150.

The anodic aluminum oxide film structure 10 according to the third embodiment includes both a configuration in which an inner metal layer 200 is formed around a through-hole 150 so that the inner metal layer 200 is not exposed toward the through-hole 150 and a configuration in which an inner metal layer 200 is exposed toward a through-hole 150.

Among a plurality of through-holes 150, inner metal layers 200 are provided on inner walls of at least portions of the through-holes 150, and an anodic aluminum oxide film is provided on inner walls of the remaining portions of the through-holes 150. With this, the at least the portions of the through-holes 150 can be electrically connected to the inner metal layers 200, and the remaining portions of the through-holes 150 are not electrically connected to the inner metal layers 200.

An electrically conductive contact pin 20 is provided in each of the through-holes 150. Among a plurality of electrically conductive contact pins, at least portions of the electrically conductive contact pins 20 may be electrically connected to each other through the inner metal layers 200 and surface metal layers 300, and the remaining portions of the electrically conductive contact pins 20 may be maintained in an electrically insulated state by the anodic aluminum oxide film provided on the inner walls of the through-holes 150.

The electrically conductive contact pin 20 may be a contact pin 20 for transmitting a ground signal, a contact pin 20 for transmitting a power signal, or a contact pin 20 for transmitting an operation signal. For example, in the case of the contact pin 20 for transmitting a ground signal, a plurality of contact pins 20 for transmitting a ground signal may be connected to each other as a group through the inner metal layers 200 and the surface metal layers 300 and commonly grounded. In this case, contact pins 20 for transmitting an operation signal may be inserted into the through-holes 150 having the inner walls provided with the anodic aluminum oxide film and electrically insulated from the contact pins 20 for transmitting a ground signal.

### Fourth Embodiment

Next, the fourth embodiment according to the present disclosure will be described. However, the embodiments described below will be mainly described in terms of characteristic elements in comparison with the first to third embodiments, and descriptions of the same or similar elements to the first to third embodiments will be omitted.

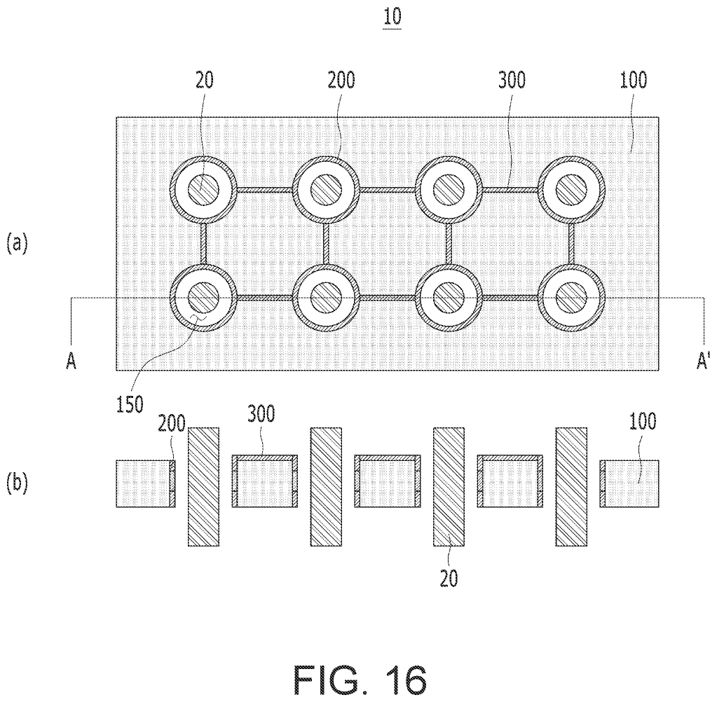

Hereinafter, an anodic aluminum oxide film structure according to the fourth embodiment of the present disclosure will be described with reference to FIGS. 16(a) and 16(b). FIG. 16(a) is a plan view illustrating the anodic aluminum oxide film structure 10 according to the fourth embodiment of the present disclosure. FIG. 16(b) is a sectional view taken along line A-A′ of FIG. 16(a).

The anodic aluminum oxide film structure 10 according to the fourth embodiment of the present disclosure remains the same as the anodic aluminum oxide film structures 10 according to the first to third embodiments of the present disclosure, except for the configuration of an inner metal layer 200.

In the fourth embodiment, each inner metal layer 200 is formed by stacking a plurality of metal layers in the thickness direction of a body 100. Here, the plurality of metal layers may be made of different materials.

When a slidable part (e.g., an electrically conductive contact pin 20) is provided in each through-hole 150, a sufficient gap may exist between the part and the through-hole 150 so that the part can more easily slide in the through-hole 150. In this case, since the part slides vertically in the through-hole 150 in an inclined state, a contact pressure at upper and lower ends of the through-hole 150 may be large. Therefore, in order to prevent an inner wall of the through-hole 150 from being worn, among the metal layers provided on the inner wall of the through-hole 150, the top and bottom metal layers may be made of a metal having higher wear resistance than the metal layers in other areas.

### Fifth Embodiment

Next, the fifth embodiment according to the present disclosure will be described. However, the embodiments described below will be mainly described in terms of characteristic elements in comparison with the first to third embodiments, and descriptions of the same or similar elements to the first to third embodiments will be omitted.

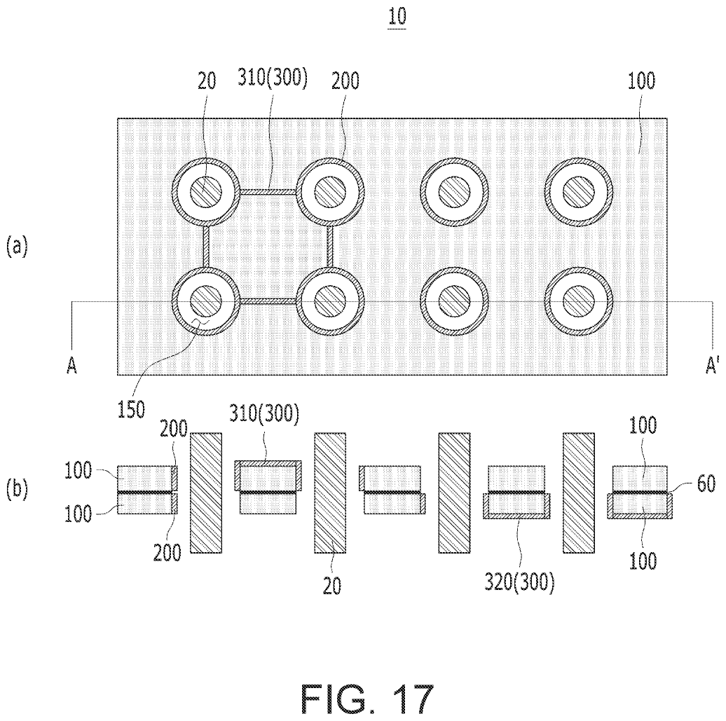

Hereinafter, an anodic aluminum oxide film structure 10 according to the fifth embodiment of the present disclosure will be described with reference to FIGS. 17(a) and 17(b). FIG. 17(a) is a plan view illustrating the anodic aluminum oxide film structure 10 according to the fifth embodiment of the present disclosure. FIG. 17(b) is a sectional view taken along line A-A′ of FIG. 17(a).

In the fifth embodiment, a plurality of bodies 100 are stacked on each other. When one body 100 made of an anodic aluminum oxide film is provided, the body has a thickness in the range of tens to hundreds of μm. In this case, using the body as a structure may be disadvantageous in terms of strength. Thus, the strength of the anodic aluminum oxide film structure 10 can be improved by stacking the plurality of bodies 100 made of the anodic aluminum oxide film and bonding them with a bonding layer 60.

Inner metal layers 200 formed in the respective bodies may be provided at the same position with respect to respective vertical lines, or may be provided at different positions with respect to the respective vertical lines.

For one through-hole 150, the bodies 100 may be stacked so that an inner metal layer 200 is provided on an inner wall of the through-hole 150. Alternatively, for one through-hole 150, the bodies 100 may be stacked so that an inner metal layer 200 and the anodic aluminum oxide film are provided on an inner wall of the through-hole 150.

Among adjacent through-holes 150, an inner metal layer 200 may be provided on an inner wall of one through-hole 150 in the upper body 100, and an inner metal layer 200 may be provided on an inner wall of the other through-hole 150 in the lower body 100. In this case, an upper surface metal layer 310 is electrically connected to the inner metal layer 200 of the upper body 100, and a lower surface metal layer 350 is electrically connected to the inner metal layer 200 of the lower body 100.

### Sixth Embodiment

Next, the sixth embodiment according to the present disclosure will be described. However, the embodiments described below will be mainly described in terms of characteristic elements in comparison with the first to third embodiments, and descriptions of the same or similar elements to the first to third embodiments will be omitted.

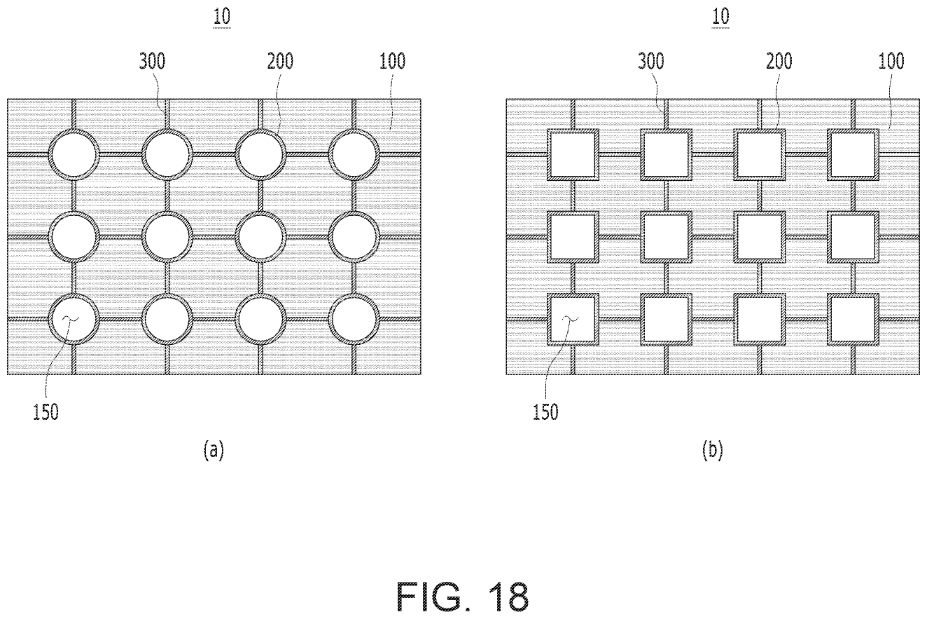

Hereinafter, an anodic aluminum oxide film structure 10 according to the sixth embodiment of the present disclosure will be described with reference to FIGS. 18(a) and 18(b).

In the sixth embodiment, inner metal layers 200 have a circular cross-section and a square cross-section, and may also have cross-sections of other shapes. Each surface metal layer 300 may be provided to connect adjacent inner metal layers 200 to each other via a shortest distance.

Each surface metal layer 300 may have a first end connected to an inner metal layer 200 and a second end extending toward an outer edge of the body 100. With this, surface metal layers 300 can be grounded easily.

In addition, the surface metal layers 300 illustrated in FIGS. 18(a) and 18(b) may further include a surface metal layer passing through the body 100 in the thickness direction. In this case, in the same manner as the method of forming an inner metal layer 200, an inner space passing through the body 100 may be provided and the inner space may be filled with a metal material to form the surface metal layer 300 having a through-structure. The surface metal layer 300 may be formed together with the inner metal layer 200 when the inner metal layer is formed by filling an inner space 40 with a metal material.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

10: anodic aluminum oxide film structure
20: electrically conductive contact pin
100: body
150: through-hole
200: inner metal layer
300: surface metal layer

1. An anodic aluminum oxide film structure, comprising:
a body made of an anodic aluminum oxide film that is formed by anodizing a base metal and then removing the base metal;
a plurality of through-holes formed through the body and having a larger inner width than pores formed during anodization; and
a plurality of inner metal layers provided inside the body.

2. The anodic aluminum oxide film structure of claim 1, further comprising:
a surface metal layer formed on a surface of the body,
wherein the surface metal layer is connected to each of the inner metal layers.

3. The anodic aluminum oxide film structure of claim 1, wherein each of the inner metal layers is formed on an inner wall of each of the through-holes and is exposed toward the through-hole.

4. The anodic aluminum oxide film structure of claim 1, wherein each of the inner metal layers is formed around each of the through-holes and is not exposed toward the through-hole.

5. The anodic aluminum oxide film structure of claim 1, wherein each of the inner metal layers is formed to surround at least a portion of each of the through-holes, and the anodic aluminum oxide film exists between each of the inner metal layers and each of the through-holes.

6. The anodic aluminum oxide film structure of claim 1, further comprising:
an upper surface metal layer formed on an upper surface of the body; and
a lower surface metal layer formed on a lower surface of the body.

7. The anodic aluminum oxide film structure of claim 1, wherein each of the inner metal layers is formed by stacking a plurality of metal layers in a thickness direction of the body.

8. The anodic aluminum oxide film structure of claim 1, wherein the body comprises a plurality of bodies stacked on each other.

9. The anodic aluminum oxide film structure of claim 1, wherein the body comprises a plurality of bodies stacked on each other, and
inner metal layers formed in the respective bodies are provided at the same position with respect to respective vertical lines.

10. The anodic aluminum oxide film structure of claim 1, wherein the body comprises a plurality of bodies stacked on each other, and
inner metal layers formed in the respective bodies are provided at different positions with respect to respective vertical lines.

11. The anodic aluminum oxide film structure of claim 1, further comprising:
a surface metal layer formed on a surface of the body and connecting the plurality of inner metal layers to each other,
wherein the surface metal layer is grounded.

12. An anodic aluminum oxide film structure, comprising:
a body made of an anodic aluminum oxide film that is formed by anodizing a base metal and then removing the base metal;
a plurality of through-holes formed through the body and having a larger inner width than pores formed during anodization;
a plurality of inner metal layers each of which is provided on an inner wall of each of the through-holes to prevent the anodic aluminum oxide film from being exposed toward the through-hole; and
a surface metal layer formed on a surface of the body to connect the plurality of inner metal layers to each other.

13. The anodic aluminum oxide film structure of claim 12, further comprising:
a plurality of fine trenches having a depth and a width and formed on a surface of each of the inner metal layer,
wherein the fine trenches are formed to extend in a thickness direction of the body, and
the fine trenches are repeatedly formed in a circumferential direction of each of the through-holes.

14. The anodic aluminum oxide film structure of claim 13, wherein the depth and the width of the fine trenches range from 20 nm to 1 μm.

15. An anodic aluminum oxide film structure, comprising:
a body made of an anodic aluminum oxide film that is formed by anodizing a base metal and then removing the base metal; and
an inner metal layer provided inside the body,
wherein the inner metal layer is provided with a plurality of fine trenches that are formed at a bonding interface between the inner metal layer and the body and are in close contact with inner walls of pores of the body.
